(19) United States
(12) Patent Application Publication
(10) Pub. No.: US 2013/0088912 A1
(43) Pub. Date: Apr. 11, 2013

(54) SEMICONDUCTOR MEMORY DEVICE

(71) Applicants: Jong-pil SON, Seongnam-si (KR); Dong-min KIM, Hwaseong-si (KR)

(72) Inventors: Jong-pil SON, Seongnam-si (KR); Dong-min KIM, Hwaseong-si (KR)

(21) Appl. No.: 13/535,583

(22) Filed: Jun. 28, 2012

(30) Foreign Application Priority Data
Oct. 7, 2011 (KR) 10-2011-0102653

(51) Int. Cl. G11C 7/06; G11C 11/24; G11C 7/00

(52) U.S. Cl. 365/149; 365/190; 365/208

(57) ABSTRACT

A semiconductor memory device includes a first bit line to which a first memory cell is connected, and a second bit line to which a second memory cell is connected, the second bit line being complementary to the first bit line, a sense amplifier that includes a first transistor and a second transistor connected in series between the first bit line and the second bit line, the sense amplifier including a first node between the first transistor and the second transistor, a gate of the first transistor being connected to the second bit line, and a gate of the second transistor being connected to the first bit line, and a voltage providing unit that provides a first voltage to the first node during presensing, and provides a second voltage, different from the first voltage, to the first node during main sensing.

### CROSS-REFERENCE TO RELATED APPLICATIONS

This application claims the benefit of Korean Patent Application No. 10-2011-0102653, filed on Oct. 7, 2011, in the Korean Intellectual Property Office, the disclosure of which is incorporated herein in its entirety by reference.

### BACKGROUND

1. Field

Embodiments relate to a semiconductor memory device.

2. Description of the Related Art

A dynamic random-access memory (DRAM), which is a semiconductor memory device, senses and amplifies data stored in a memory cell by using a sense amplifier. The sense amplifier may sense the data stored in the memory cell by comparing a voltage of a bit line with a voltage of a complementary bit line that are changed after charge sharing.

### SUMMARY

Embodiments are directed to a semiconductor memory device, operations of which include precharging, charge sharing, presensing, and main sensing that are sequentially performed, the semiconductor memory device including a first bit line to which a first memory cell is connected, and a second bit line to which a second memory cell is connected, the second bit line being complementary to the first bit line, a sense amplifier that includes a first transistor and a second transistor connected in series between the first bit line and the second bit line, the sense amplifier including a first node between the first transistor and the second transistor, a gate of the first transistor being connected to the second bit line, and a gate of the second transistor being connected to the first bit line, and a voltage providing unit that provides a first voltage to the first node during the presensing, and provides a second voltage, different from the first voltage, to the first node during the main sensing.

The first memory cell may include a first switching element and a first capacitor, the first switching element including a control terminal connected to a first word line, a first terminal connected to the first bit line, and a second terminal connected to a first terminal of the first capacitor, and the first capacitor including a second terminal to which a first plate voltage is provided, the second memory cell may include a second switching element and a second capacitor, the second switching element including a control terminal connected to a second word line, a first terminal connected to the second bit line, and a second terminal connected to a first terminal of the second capacitor, and the second capacitor including a second terminal to which a second plate voltage is provided, and the second plate voltage may be changed independently of the first plate voltage.

The first bit line and the second bit line may be precharged to a power supply voltage during the precharging, and the voltage providing unit may provide the first voltage, which is greater than the second voltage, to the first node during the presensing.

The second voltage may be the power supply voltage, the first voltage may be greater than the second voltage by a predetermined amount, and the predetermined amount may be adjustable.

The first bit line and the second bit line may be precharged to a ground voltage during the precharging, and the voltage providing unit may provide the first voltage, which is less than the second voltage, to the first node during the presensing.

The second voltage may be the ground voltage, the first voltage may be less than the second voltage by a predetermined amount, and the predetermined amount may be adjustable.

The first bit line and the second bit line may be precharged to a third voltage, which is greater than a ground voltage and less than a power supply voltage, during the precharging, and the first voltage may be between the second voltage and the third voltage.

The voltage providing unit may include a voltage supply source that provides the second voltage, a first switching element that applies the second voltage of the voltage supply source to the first node during the main sensing, a voltage dropping element that generates the first voltage from the second voltage of the voltage supply source, and a second switching element that applies the first voltage to the first node by using the voltage dropping element during the presensing.

The voltage dropping element may be a transistor or a diode.

The first voltage may be greater or less than the second voltage by a threshold voltage of the voltage dropping element.

The threshold voltage may be adjusted by adjusting an impurity concentration of the voltage dropping element.

The voltage supply source may provide the second voltage, which is greater than the power supply voltage and less than the ground voltage, during the charge sharing and the presensing.

The sense amplifier may include a first amplifying unit including the first transistor and the second transistor, and a second amplifying unit including a third transistor and a fourth transistor, the third transistor may include a first terminal connected to the first bit line, a gate connected to the second bit line, and a second terminal connected to a second node, the fourth transistor may include a first terminal connected to the second bit line, a gate connected to the first bit line, and a second terminal connected to the second node, and the voltage providing unit may provide a fourth voltage to the second node during the main sensing, and provide a fifth voltage, which is between the fourth voltage and the third voltage, to the second node during the presensing.

One of the second voltage and the fourth voltage may be the power supply voltage, and the other one may be the ground voltage.

Embodiments are also directed to a semiconductor memory device, operations of which include precharging, charge sharing, presensing, and main sensing that are sequentially performed, the semiconductor memory device including a first bit line and a second bit line that are complementary to each other and are precharged to a first voltage which is greater than a ground voltage and less than a power supply voltage, a first transistor that includes a first terminal connected to the first bit line, a gate connected to the second bit line, and a second terminal connected to a first node, a second transistor that includes a first terminal connected to the second bit line, a gate connected to the first bit line, and a second terminal connected to the first node, and a voltage providing unit that provides a second voltage to the first node during the main sensing, and provides a third voltage, which is between the first voltage and the second voltage, to the first node during the presensing.

Embodiments are directed to a semiconductor memory device, including a first bit line, a second bit line, a sense amplifier, the sense amplifier having a first transistor connected to the first bit line and having a second transistor connected to the second bit line, the first and second transistors being connected to each other in series between the first and second bit lines, and a voltage providing unit coupled to a node in the sense amplifier between the first and second transistors, the voltage providing unit providing an adjustable voltage to the node, the voltage being adjusted to a first level during a presensing operation, during which a voltage difference between the first bit line and the second bit line is amplified by the sense amplifier, and being adjusted to a second level during a main sensing operation, which immediately follows the presensing operation and during which the sense amplifier further amplifies the voltage difference, the second level being different from the first level.

The first and second transistors may each be PMOS transistors, and the first level may be greater than the second level.

The semiconductor memory device may be supplied with a power supply voltage and a ground voltage, the power supply voltage being greater than the ground voltage, and the second level may be equal to the power supply voltage.

The first and second transistors may each be NMOS transistors, and the first level may be less than the second level.

The semiconductor memory device may be supplied with a power supply voltage and a ground voltage, the power supply voltage being greater than the ground voltage, and the second level may be equal to the ground voltage.

### BRIEF DESCRIPTION OF THE DRAWINGS

Features will become apparent to those of skill in the art by describing in detail exemplary embodiments with reference to the attached drawings in which:

FIG. 1 illustrates a circuit diagram of a semiconductor memory device according to an embodiment;

FIG. 2 illustrates a circuit diagram of a semiconductor memory device according to another embodiment;

FIG. 3 illustrates a timing diagram for explaining a method of sensing data that is performed by the semiconductor memory device of FIG. 2, according to an embodiment;

FIG. 4 illustrates a graph of a result obtained after a simulation is performed on the semiconductor memory device of FIG. 2;

FIG. 5 illustrates a circuit diagram of a semiconductor memory device according to another embodiment;

FIG. 6 illustrates a timing diagram for explaining a method of sensing data that is performed by the semiconductor memory device of FIG. 5, according to an embodiment;

FIG. 7 illustrates a circuit diagram of a semiconductor memory device according to another embodiment;

FIG. 8 illustrates a timing diagram for explaining a method of sensing data that is performed by the semiconductor memory device of FIG. 7, according to an embodiment;

FIGS. 9A through 9E illustrate circuit diagrams of modified examples of the semiconductor memory device of FIG. 7; and

FIGS. 10A and 10B illustrate timing diagrams for explaining a method of sensing data that is performed by modified examples of the semiconductor memory device of FIG. 7, according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. Like reference numerals refer to like elements throughout.

It will be understood that, although the terms “first,” “second,” “third,” etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of exemplary embodiments. As used herein, the term “and/or” includes any and all combinations of one or more of the associated listed items.

It will be understood that when an element, such as a layer, a region, or a substrate, is referred to as being “on,” “connected to,” or “coupled to” another element, it may be directly on, connected to, or coupled to the other element, or intervening elements may be present. In contrast, when an element is referred to as being “directly on,” “directly connected to,” or “directly coupled to” another element or layer, there are no intervening elements or layers present. Other words used to describe the relationship between elements or layers should be interpreted in a like fashion (e.g., “between” versus “directly between,” “adjacent” versus “directly adjacent,” etc.).

The terminology used herein is for the purpose of describing particular embodiments only and is not intended to be limiting of exemplary embodiments. As used herein, the singular forms “a,” “an,” and “the” are intended to include the plural forms as well, unless the context clearly indicates otherwise. It will be further understood that the terms “comprises” and/or “comprising” used herein specify the presence of stated features, integers, steps, operations, members, components, and/or groups thereof, but do not preclude the presence or addition of one or more other features, integers, steps, operations, members, components, and/or groups thereof.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

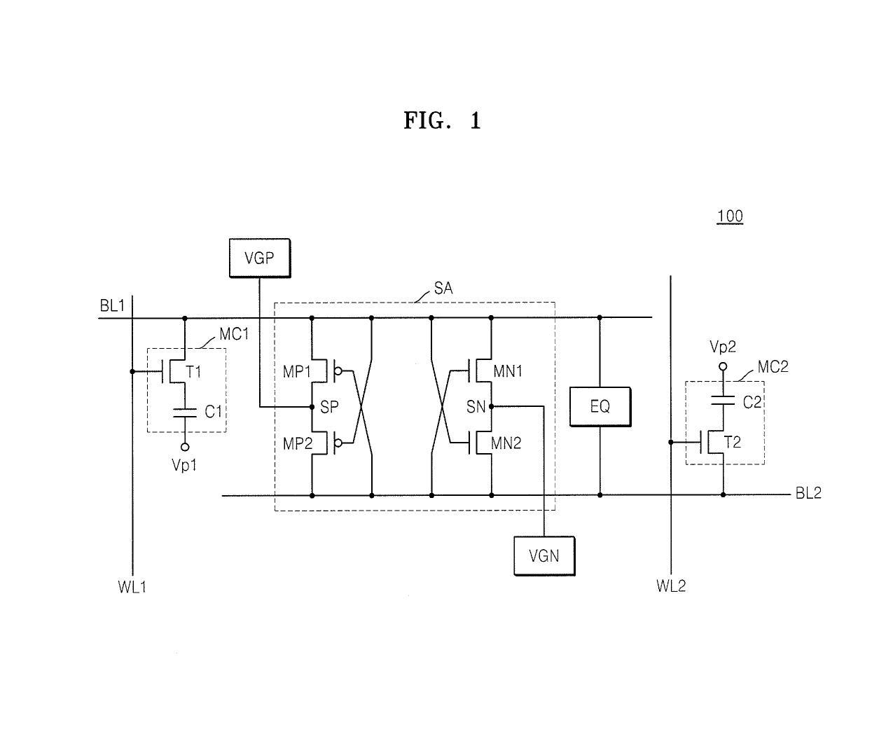

FIG. 1 illustrates a circuit diagram of a semiconductor memory device 100 according to an embodiment.

In the example embodiment shown in FIG. 1, the semiconductor memory device 100 includes a first bit line BL1 and a second bit line BL2, a sense amplifier SA that is disposed between the first bit line BL1 and the second bit line BL2, and first and second voltage providing units VGP and VGN that provide a voltage for driving the sense amplifier SA. The semiconductor memory device 100 may be, for example, a dynamic random access memory (DRAM) in FIG. 1.

In the present example embodiment, a first memory cell MC1, which includes a first switching transistor T1 and a first capacitor C1, is connected to the first bit line BL1. The first switching transistor T1 includes a gate to which a first word line WL1 is connected, a first terminal connected to the first bit line BL1, and a second terminal connected to a first terminal of the first capacitor C1. A first plate voltage Vp1 is provided to a second terminal of the first capacitor C1.

A second memory cell MC2 including a second switching transistor T2 and a second capacitor C2 is connected to the second bit line BL2. The second switching transistor T2 includes a gate to which a second word line WL2 is connected, a first terminal connected to the second bit line BL2, and a second terminal connected to a first terminal of the second capacitor C2. A second plate voltage Vp2 is provided to a second terminal of the second capacitor C2.

A first terminal and a second terminal of a transistor herein below refer to terminals that are closed or opened each other according to a control signal applied to a gate. A first terminal and a second terminal of one device do not have a limited meaning but are used to be distinguished from each other.

The first plate voltage Vp1 and the second plate voltage Vp2 may be different and may change independently. To this end, the second terminal of the first capacitor C1 to which the first plate voltage Vp1 is applied and the second terminal of the second capacitor C2 to which the second plate voltage Vp2 is applied may be electrically isolated from each other. Alternatively, the first plate voltage Vp1 and the second plate voltage Vp2 may be the same, and the second terminal of the first capacitor C1 to which the first plate voltage Vp1 is applied and the second terminal of the second capacitor C2 to which the second plate voltage Vp2 is applied may be electrically connected to each other.

The first memory cell MC1 may be a main memory cell for storing data, and the second memory cell MC2 may be a reference cell for adjusting a voltage of the second bit line BL2 in order to sense data of the first memory cell MC1. Although a reference cell has the same structure as that of a main memory cell except that a second terminal of a capacitor may be independently controlled, the reference cell does not store data. A main memory cell may be generally referred to as a memory cell and a reference cell may be referred to as a reference voltage generating unit. On the contrary, the second memory cell MC2 may be a main memory cell and the first memory cell MC1 may be a reference cell. Alternatively, both the first memory cell MC1 and the second memory cell MC2 may be main memory cells for storing data.

FIG. 1 shows only the first memory cell MC1 is connected to the first bit line BL1 and only the second memory cell MC2 is connected to the second bit line BL2. However, this example is merely for ease of understanding. For example, a plurality of main memory cells may be connected to the first bit line BL1 and at least one reference cell may also be connected to the first bit line BL1. A plurality of main memory cells may be connected to the second bit line BL2 and at least one reference cell may also be connected to the second bit line BL2.

If the first memory cell MC1 is a main memory cell, when the first word line WL1 connected to the gate of the first memory cell MC1 is activated, the first capacitor C1 may be charged by applying a voltage (for example, a power supply voltage Vdd, corresponding to data to be stored in the first capacitor C1 of the first memory cell MC1) to the first bit line BL1. In this case, a half of the power supply voltage, that is, Vdd/2, may be applied to the second terminal of the first capacitor C1. If the second memory cell MC2 is a main memory cell, the same method may be used. If the first memory cell MC1 is a reference cell, a voltage applied to the second terminal of the first capacitor C1 may be changed. The power supply voltage Vdd may range, for example, from 1 to 1.2 V, and in this case, the first and second memory cells MC1 and MC2 may operate at a voltage less than 1 V.

The sense amplifier SA is a circuit for sensing and amplifying data stored in a main memory cell. The sense amplifier SA may include a first amplifying unit and a second amplifying unit. The first amplifying unit may include a first transistor MP1 and a second transistor MP2. The first transistor MP1 and the second transistor MP2 may be designed to have a same aspect ratio. The first amplifying unit may be referred to as a P-type latch. The second amplifying unit may include a third transistor MN1 and a fourth transistor MN2. The first transistor MP1 and the second transistor MP2 may be PMOS transistors, and the third transistor MN1 and the fourth transistor MN2 may be NMOS transistors. The third transistor MN1 and the fourth transistor MN2 may be designed to have a same aspect ratio. The second amplifying unit may be referred to as an N-type latch.

In the present example embodiment, the first transistor MP1 switches a connection between the first bit line BL1 and a first node SP according to a voltage of the second bit line BL2 connected to a control terminal of the first transistor MP1. The second transistor MP2 switches a connection between the second bit line BL2 and the first node SP according to a voltage of the first bit line BL1 connected to a control terminal of the second transistor MP2. The first transistor MP1 and the second transistor MP2 may constitute a latch.

In the present example embodiment, the first voltage providing unit VGP is connected to the first node SP. The first voltage providing unit VGP may provide a predetermined voltage to the first node SP. A voltage provided by the first voltage providing unit VGP during presensing may be different from a voltage provided by the first voltage providing unit VGP during main sensing. For example, the first voltage providing unit VGP may provide the power supply voltage Vdd to the first node SP during main sensing, and may provide a voltage greater than the power supply voltage Vdd (for example, 1.2 times the power supply voltage 1.2 Vdd) during presensing. In another embodiment, the first voltage providing unit VGP may provide the power supply voltage Vdd to the first node SP during main sensing, and may provide a voltage less than the power supply voltage Vdd during presensing.

The third transistor MN1 switches a connection between the first bit line BL1 and a second node SN according to a voltage of the second bit line BL2 connected to a control terminal of the third transistor MN1. The fourth transistor MN2 switches a connection between the second bit line BL2 and the second node SN according to a voltage of the first bit line BL1 connected to a control terminal of the fourth transistor MN2. The third transistor MN1 and the fourth transistor MN2 may constitute a latch.

In the present example embodiment, the second voltage providing unit VGN is connected to the second node SN. The second voltage providing unit VGN may provide a predetermined voltage to the second node SN. A voltage provided by the second voltage providing unit VGN during presensing may be different from a voltage provided by the second voltage providing unit VGN during main sensing. For example, the second voltage providing unit VGN may provide a ground voltage Vss (GND) to the second node SN during main sensing, and may provide a voltage less than the ground voltage Vss (for example, −0.2 times the power supply voltage−0.2 Vdd) during presensing. In another embodiment, the second voltage providing unit VGN may provide the ground voltage Vss to the second node SN during main sensing, and may provide a voltage greater than the ground voltage Vss during presensing.

As shown in FIG. 1, the semiconductor memory device 100 may further include an equalizing unit EQ. The equalizing unit EQ (which is connected between the first bit line BL1 and the second bit line BL2) may equalize the first bit line BL1 and the second bit line BL2 to a predetermined voltage. For example, the equalizing unit EQ may equalize the first bit line BL1 and the second bit line BL2 to any one of the power supply voltage Vdd, a half of the power supply voltage Vdd (that is, Vdd/2), and the ground voltage Vss.

An example embodiment of a method of sensing data performed by the semiconductor memory device 100 of FIG. 1 will now be explained assuming that data stored in the first memory cell MC1 is read out.

In the present example embodiment, the method of sensing data performed by the semiconductor memory device 100 includes a precharging operation, a charge sharing operation, a presensing operation, and a main sensing operation. In a precharging operation, the first bit line BL1 and the second bit line BL2 may be precharged to a first voltage using the equalizing unit EQ. In some embodiments, the first voltage may be a half of the power supply voltage Vdd, that is, Vdd/2, the power supply voltage Vdd, or the ground voltage Vss.

Next, in a charge sharing operation, a word line (the first word line WL1 in the present embodiment) to which a memory cell (the first memory cell MC1 in the present embodiment) for sensing data is connected is activated. Accordingly, the first switching transistor T1 is turned on, and the first capacitor C1 and a bit line capacitor induced between the first and second bit lines BL1 and BL2 are connected to each other. As charges move through the first switching transistor T1 between the bit line capacitor and the first capacitor C1, a voltage of the first bit line BL1 (to which the first memory cell MC1 is connected) is changed.

It is assumed that when the first plate voltage Vp1 applied to the second terminal of the first capacitor C1 is Vdd/2, and a voltage of the first terminal of the first capacitor C1 is the power supply voltage Vdd, data “1” is stored, and when a voltage of the first terminal of the first capacitor C1 is the ground voltage Vss, data “1” is stored.

When the first and second bit lines BL1 and BL2 are precharged to Vdd/2 and data “1” is stored in the first capacitor C1, a voltage of the first bit line BL1 is increased in the charge sharing operation. When data “0” is stored in the first capacitor C1, a voltage of the first bit line BL1 is decreased in the charge sharing operation. Such a change in the voltage may be sensed and amplified in a presensing operation and a main sensing operation.

In another embodiment, when the first and second bit lines BL1 and BL2 are precharged to the power supply voltage Vdd and data “0” is stored in the first capacitor C1, a voltage of the first bit line BL1 may be decreased in the charge sharing operation. However, when data “1” is stored in the first capacitor C1, a voltage of the first bit line BL1 may not be changed in the charge sharing operation. In order to sense this, the second plate voltage Vp2 applied to the second terminal of the capacitor C2 of the second memory cell MC2 connected to the second bit line BL2 may be reduced by a predetermined amount. When the second plate voltage Vp2 is reduced, a voltage of the second bit line BL2 is reduced due to capacitive coupling. To this end, the second word line WL2 connected to the second memory cell MC2 is activated to turn on the second switching transistor T2. However, a decrement in a voltage of the second bit line BL2 due to capacitive coupling should be less than a decrement in a voltage of the first bit line BL1 that occurs in the charge sharing operation when data “0” is stored in the first capacitor C1. A change in the voltage of the second bit line BL2 may be sensed and amplified during a presensing operation and a main sensing operation to determine that data stored in the first memory cell MC1 is “1”. In this case, the second memory cell MC2 connected to the second bit line BL2 functions as a reference cell.

When the first and second bit lines BL1 and BL2 are precharged to the ground voltage Vss and data “1” is stored in the first capacitor C1, a voltage of the first bit line BL1 may be increased to be sensed during the charge sharing operation. However, when data “0” is stored in the first capacitor C1, a voltage of the first bit line BL1 may not be changed during the charge sharing operation. In order to sense this, the second plate voltage Vp2 (applied to the second terminal of the capacitor C2 of the second memory cell MC2 connected to the second bit line BL2) is increased by a predetermined amount. When the second plate voltage Vp2 is increased, a voltage of the second bit line BL2 is increased to be sensed due to capacitive coupling. However, an increment in a voltage of the second bit line BL2 due to capacitive coupling should be less than an increment in a voltage of the first bit line BL1 that occurs in the charge sharing operation when data “1” is stored in the first capacitor C1. A change in the voltage of the second bit line BL2 may be sensed and amplified during a presensing operation and a main sensing operation to determine that data stored in the first memory cell MC1 is “0”. In this case, the second memory cell MC2 connected to the second bit line BL2 functions as a reference cell.

Next, in a presensing operation, a difference between a voltage of the first bit line BL1 and a voltage of the second bit line BL2 is amplified. The sense amplifier SA may include the first through fourth transistors MP1, MP2, MN1, and MN2 as described above. The first and second transistors MP1 and MP2 increase a voltage of a bit line having a higher voltage level from among the first bit line BL1 and the second bit line BL2 to a voltage that is applied to the first node SP. The third and fourth transistors MN1 and MN2 reduce a voltage of a bit line having a lower voltage level from among the first bit line BL1 and the second bit line BL2 to a voltage that is applied to the second node SN. A difference between the voltage of the first bit line BL1 and the voltage of the second bit line BL2 may be amplified by adjusting voltages applied to the first node SP and/or the second node SN during the presensing operation, to achieve a sufficient sensing margin for a subsequent main sensing operation.

Next, in a main sensing operation, as the difference between the voltage of the first bit line BL1 and the voltage of the second bit line BL2 is sensed and amplified by using the sense amplifier SA, data stored in a memory cell is identified. A sufficient sensing margin is achieved during the presensing operation. Thus, the sense amplifier SA may reliably identify the data stored in the memory cell during the main sensing operation. In the present embodiment, the first voltage providing unit VGP may provide the power supply voltage Vdd to the first node SP and may provide the ground voltage Vss to the second node SN during the main sensing operation.

A voltage provided to the first node SP and/or the second node SN during the presensing operation may be different from a voltage provided to the first node SP and/or the second node SN during the main sensing operation.

Semiconductor memory devices according to various embodiments will now be described.

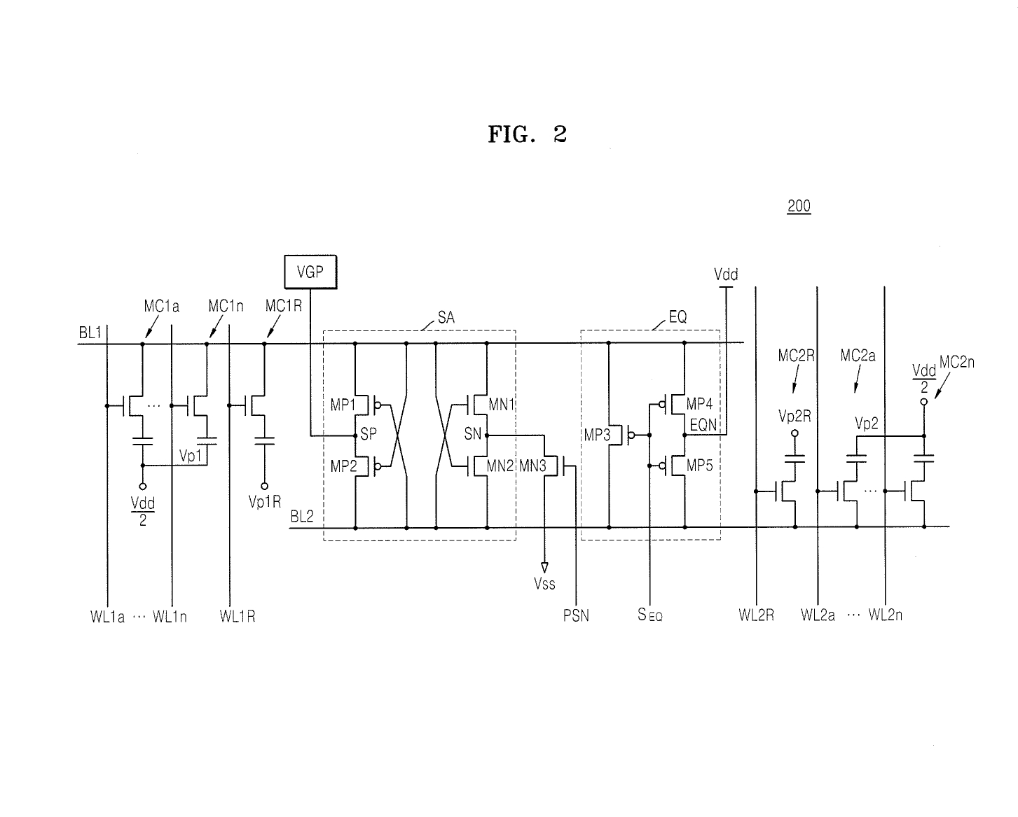

FIG. 2 illustrates a circuit diagram of a semiconductor memory device 200 according to another example embodiment.

In the example embodiment shown in FIG. 2, the semiconductor memory device 200 includes the first bit line BL1 and the second bit line BL2, first memory cells MC1a through MC1n, second memory cells MC2a through MC2n, and first and second reference cells MC1R and MC2R connected to the first and second bit lines BL1 and BL2, the sense amplifier SA, and the equalizing unit EQ. Details of the same elements as those of the semiconductor memory device 100 of FIG. 1 will not be repeated.

The plurality of first memory cells MC1a through MC1n and the first reference cell MC1R are connected to the first bit line BL1. Also, the plurality of second memory cells MC2a through MC2n and the second reference cell MC2R are connected to the second bit line BL2. The first memory cells MC1a through MC1n and the second memory cells MC2a through MC2n may be memory cells for storing data of 1 bit, and the first reference cell MC1R and the second reference cell MC2R may be cells used to sense data of the second memory cells MC2a through MC2n and the first memory cells MC1a through MC1n.

Plate voltages Vp1 and Vp2 may be provided to second terminals of capacitors of the first memory cells MC1a through MC1n and the second memory cells MC2a through MC2n. The plate voltages Vp1 and Vp2 may be a half of the power supply voltage Vdd, that is, Vdd/2. The second terminals of the capacitors of the first memory cells MC1a through MC1n and the second memory cells MC2a through MC2n may be connected to each other, and may be commonly controlled.

Reference plate voltages Vp1R and Vp2R may be provided to second terminals of capacitors of the first reference cell MC1R and the second reference cell MC2R, respectively. Each of the reference plate voltages Vp1R and Vp2R may be the power supply voltage Vdd during precharging and may be a voltage less than the power supply voltage Vdd, for example, Vdd/2, during charge sharing, presensing, and main sensing. The second terminal of the capacitor of the first reference cell MC and the second terminal of the capacitor of the second reference cell MC2R may be electrically connected to each other, and may be commonly controlled.

The equalizing unit EQ may include first through third equalizing transistors MP3, MP4, and MP5. A control signal S_{EQ} may be provided to gates of the first through third equalizing transistors MP3, MP4, and MP5. The first equalizing transistor MP3 may connect the first bit line BL1 and the second bit line BL2 together in response to the control signal S_{EQ}. The second equalizing transistor MP4 and the third equalizing transistor MP5 may equalize the first bit line BL1 and the second bit line BL2 to the power supply voltage Vdd in response to the control signal S_{EQ}. The equalizing unit EQ illustrated in FIG. 2 is one example, and may be implemented using another circuit configuration.

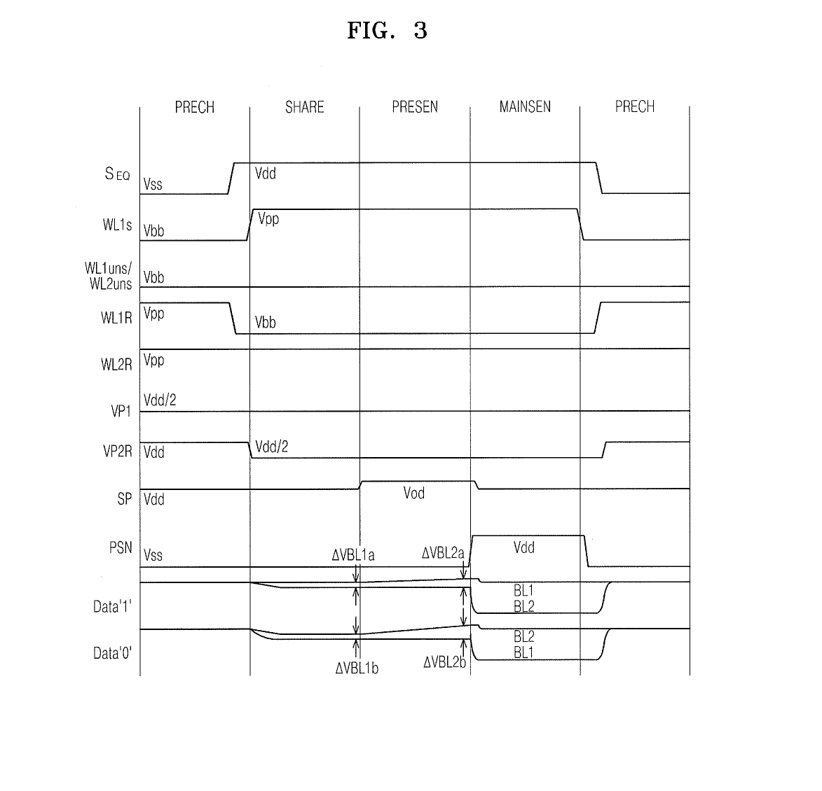

The first voltage providing unit VGP may be connected to the first node SP of the sense amplifier SA. The first voltage providing unit VGP may change a voltage of the first node SP as described above, and as explained in further detail below with reference to a timing diagram of FIG. 3.

The second node SN of the sense amplifier SA may be connected to a fifth transistor MN3 controlled by a control signal PSN, and the ground voltage Vss may be provided to the second node SN through the fifth transistor MN3.

FIG. 3 illustrates a timing diagram for explaining a method of sensing data that is performed by the semiconductor memory device 200 of FIG. 2, according to an embodiment.

Referring to FIGS. 2 and 3, the method of sensing data may include a precharging operation PRECH, a charge sharing operation SHARE, a presensing operation PRESEN, and a main sensing operation MAINSEN. After the main sensing operation MAINSEN, the precharging operation PRECH may start again.

As an example, a method of sensing data stored in one of the first memory cells MC1a through MC1n will now be explained. In this example, a word line connected to a memory cell in which data is sensed is referred as a word line WL1s, and word lines connected to the remaining memory cells are referred as word lines WL1uns and WL2uns.

In the precharge operation PRECH, the control signal S_{EQ} is the ground voltage Vss, the first through third equalizing transistors MP3, MP4, and MP5 (which are PMOS transistors) are turned on, and the first bit line BL1 and the second bit line BL2 are precharged to the power supply voltage Vdd. In this case, each of the word lines WL1a through WL1n and WL2a through WL2n connected to the first and second memory cells MC1a through MC1n and MC2a through MC2n has a low voltage Vbb, and each of the word lines WL1R and WL2R connected to the first and second reference cells MC1R and MC2R has a high voltage Vpp.

Vdd/2 is provided to the second terminals of the capacitors of the first and second memory cells MC1a through MC1n and MC2a through MC2n, and the power supply voltage Vdd is provided to the second terminal of the capacitor of the second reference cell MC2R. The first voltage providing unit VGP provides the power supply voltage Vdd to the first node SP, and the control signal PSN is disabled.

Before the charge sharing operation SHARE, the control signal S_{EQ} transits to the power supply voltage Vdd, to turn off the first through third equalizing transistors MP3, MP4, and MP5. The word line WL1R connected to the first reference cell MC1R transits to the low voltage Vbb, and the capacitor of the first reference cell MC1R is separated from the first bit line BL1.

In the charge sharing operation SHARE, the word line WL1s (connected to a memory cell in which data is to be sensed) transits to the high voltage Vpp. At this time, a voltage applied to the second terminal of the capacitor of the second reference cell MC2R is reduced to a predetermined voltage, and, thus, a voltage of the second bit line BL2 is reduced to a voltage less than the power supply voltage Vdd due to capacitive coupling. A time when the voltage applied to the second terminal of the capacitor of the second reference cell MC2R is reduced to the predetermined voltage may not be the same as a time when the word line WL1s transits to the high voltage Vpp. In the present example embodiment, the voltage applied to the second terminal of the capacitor of the second reference cell MC2R is reduced to Vdd/2. In other embodiments, the voltage may be reduced to another voltage.

For example, when the voltage applied to the second terminal of the capacitor of the second reference cell MC2R is reduced by Δv, a voltage of the second bit line BL2 is reduced by {Cs/(Cs+Cbl)}Δv. Here, Cs denotes a capacitance of the capacitor of the second reference cell MC2R, and Cbl denotes a capacitance of a bit line capacitor. An amount by which a voltage of the second bit line BL2 is reduced should be less than an amount by which a voltage of the first bit line BL1 is reduced due to charge sharing when data of a selected memory cell is “0”. However, when the data of the selected memory cell is “1”, the first bit line BL1 is maintained at the power supply voltage Vdd. Thus, an amount by which a voltage of the second bit line BL2 is reduced should be determined for the sense amplifier SA to distinguish the voltage from the power supply voltage Vdd.

When the data of the selected memory cell is “1”, the first bit line BL1 is maintained at the power supply voltage Vdd. When the data of the selected memory cell is “0”, a voltage of the first bit line BL1 is reduced to a voltage less than a voltage of the second bit line BL2 due to charge sharing.

Next, in the presensing operation PRESEN, the first voltage providing unit VGP provides an over-driving voltage Vod (which is greater than the power supply voltage Vdd) to the first node SP. For example, the over-driving voltage Vod may range from 1.1 to 1.4 times the power supply voltage Vdd. For example, the over-driving voltage Vod may be greater than the power supply voltage Vdd by 100 to 400 mV. The over-driving voltage Vod may be changed by the first voltage providing unit VGP.

As the over-driving voltage Vod is provided to the first node SP, a transistor including a gate to which a lower voltage is applied from among the first transistor MP1 and the second transistor MP2 is weakly turned on, to increase a voltage of the first bit line BL1 or the second bit line BL2. In this case, the voltage of the first bit line BL1 or the second bit line BL2 may be increased to the over-driving voltage Vod. Also, a P-type latch comprised of the first transistor MP1 and the second transistor MP2 may be designed to operate at a sub-threshold voltage.

For example, when the data of the selected memory cell is “1”, since a voltage of the second bit line BL2 is less than a voltage of the first bit line BL1 due to capacitive coupling before the presensing operation PRESEN, the first transistor MP1 having the gate connected to the second bit line BL2 is weakly turned on. As a result, the first bit line BL1 is increased to a voltage greater than the power supply voltage Vdd. Accordingly, a difference in a voltage between the first bit line BL1 and the second bit line BL2 is increased from ΔVBL1a to ΔVBL2a. The difference ΔVBL2a may be greater than the difference ΔVBL1a by, for example, 10 to 30%. Thus, a sensing margin may be increased by up to 30%.

As another example, when the data of the selected memory cell is “0”, a voltage of the first bit line BL1 is less than a voltage of the second bit line BL2 before the presensing operation PRESEN. The second transistor MP2 having the gate connected to the first bit line BL1 is weakly turned on, to increase the voltage of the second bit line BL2. As a result, a difference in a voltage between the first bit line BL1 and the second bit line BL2 is further increased, thereby increasing a sensing margin. That is, a difference in a voltage between the first bit line BL1 and the second bit line BL2 is increased from ΔVBL1b to ΔVBL2b. The difference ΔVBL2b is greater than ΔVBL1b by, for example, 10 to 30%.

A time when a voltage of the first node SP is increased is a predetermined period of time after a charge sharing operation SHARE in FIG. 3. In another embodiment, the time when the voltage of the first node SP is increased may be the same as a time when the word line WL1s of a selected memory cell transits to the high voltage Vpp. In this case, the charge sharing operation SHARE and the presensing operation PRESEN may not be distinguished from each other.

In a main sensing operation MAINSEN, the control signal PSN may transit to the power supply voltage Vdd, and the ground voltage Vss may be provided to the second node SN. As a result, a voltage of a bit line having a lower voltage from among the first bit line BL1 and the second bit line BL2 is reduced to the ground voltage Vss. When the data of the selected memory cell is “1”, a voltage of the second bit line BL2 is reduced to the ground voltage Vss, and when the data is “0”, a voltage of the first bit line BL1 is reduced to the ground voltage Vss.

Also, the first voltage providing unit VGP returns a voltage of the first node SP to the power supply voltage Vdd. As a result, when the data of the selected memory cell is “1”, a voltage of the first bit line BL1 is reduced to the power supply voltage Vdd, and when the data is “0”, a voltage of the second bit line BL2 is reduced to the power supply voltage Vdd. A time when a voltage of the first node SP is returned to the power supply voltage Vdd is slightly later than a time when the control signal PSN transits to the power supply voltage Vdd in FIG. 3. In another embodiment, the times may be substantially the same.

As a result of the main sensing operation MAINSEN, when the data of the selected memory cell is “1”, the first bit line BL1 has the power supply voltage Vdd and the second bit line BL2 has the ground voltage Vss. When the data of the selected memory cell is “0”, the first bit line BL1 has the ground voltage Vss and the second bit line BL2 has the power supply voltage Vdd. Thus, data stored in a selected memory cell is sensed and amplified. Also, when data of a capacitor of the selected memory cell is “1”, the capacitor is charged to the power supply voltage Vdd, and when the data is “0”, the capacitor is charged to the ground voltage Vss.

Next, in a precharging operation PRECH, the word line WL1s (which is a selected word line) transits to the low voltage Vbb, to separate a capacitor of a selected memory cell from a bit line and protect data stored in the capacitor. Also, the control signal PSN transits to the ground voltage Vss, and the ground voltage Vss is not provided to the second node SN. Also, the control signal S_{EQ} transits to the ground voltage Vss, to precharge the first and second bit lines BL1 and BL2 to the power supply voltage Vdd. A voltage applied to the second terminal of the capacitor of the second reference cell MC2R is returned to the power supply voltage Vdd. Even in this case, although a voltage of the second bit line BL2 should be increased due to capacitive coupling, since the second bit line BL2 is already precharged to the power supply voltage Vdd due to the control signal S_{EQ}, the voltage of the second bit line BL2 may not be increased. Also, the word line WL1R of the first reference cell MC1R connected to the first bit line BL1 is returned to the high voltage Vpp. As a result, the power supply voltage Vdd is provided to both terminals of the capacitor of the first reference cell MC1R.

It would have been understood by one of ordinary skill in the art that, although a method of sensing data stored in a memory cell connected to the first bit line BL1 is described in FIG. 3, a method of sensing data stored in a memory cell connected to the second bit line BL2 by using the first reference cell MC1R connected to the first bit line BL1 may be used.

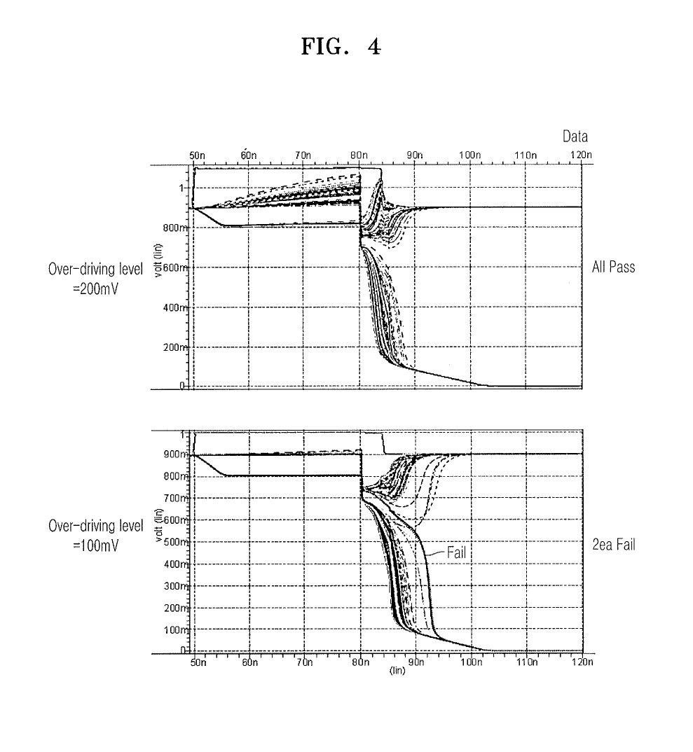

FIG. 4 illustrates a graph of a result obtained after a simulation is performed on the semiconductor memory device 200 of FIG. 2.

Referring to FIG. 4, it is illustrated whether data is successfully sensed when the power supply voltage Vdd is 900 mV and the over-driving voltage Vod is greater than the power supply voltage Vdd by 100 mV and 200 mV. In the simulation of FIG. 4, a time when a word line of a selected memory cell and a time when a voltage applied to the first node SP is over-driven were set to be substantially the same. Also, when bit lines are precharged to the power supply voltage Vdd, a voltage of a bit line when data is “0” is reduced, thereby making it easy to sense the data. However, when data is “1”, a voltage of a bit line is not changed, thereby making it difficult to sense the data. Accordingly, the simulation was performed when data stored in a selected memory cell was “1”.

Referring to the result of the simulation of FIG. 4, when the over-driving voltage Vod was greater than the power supply voltage Vdd by 100 mV, 2 of 100 cases failed. However, when the over-driving voltage Vod was greater than the power supply voltage Vdd by 200 mV, all of the 100 cases succeeded. Thus, as a voltage provided to the first node SP is over-driven, data sensing reliability may be improved. The over-driving voltage Vod may be determined based on ambient factors such as a size of a memory cell array and a size of a memory cell, and may be easily adjusted by using the first voltage providing unit VGP according to an embodiment.

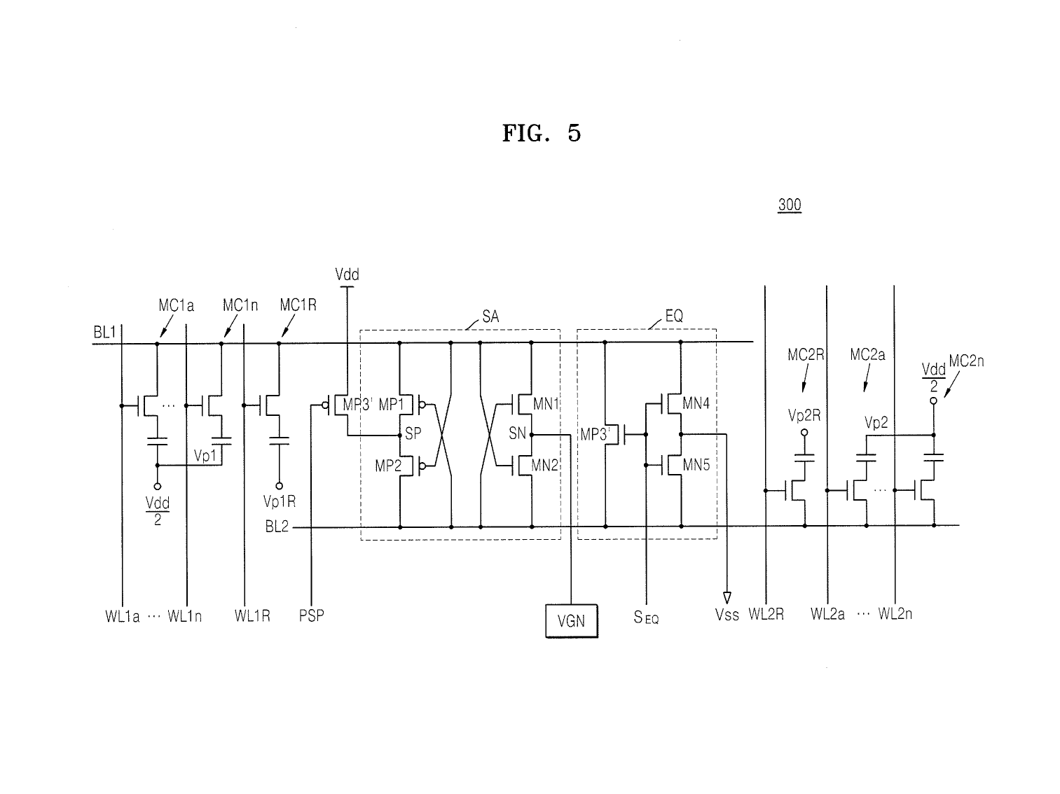

FIG. 5 illustrates a circuit diagram of a semiconductor memory device 300 according to another embodiment.

In the example embodiment shown in FIG. 5, the semiconductor memory device 300 includes the first bit line BL1 and the second bit line BL2, the first and second memory cells MC1a through MC1n and MC2a through MC2n and the first and second reference cells MC1R and MC2R connected to the first and second bit lines BL1 and BL2, the sense amplifier SA, and the equalizing unit EQ, like the semiconductor memory device 200 of FIG. 2. The semiconductor memory device 300 is similar to the semiconductor memory device 200 of FIG. 2 except that the first and second bit lines BL1 and BL2 are precharged to the ground voltage Vss. The description of same elements as those of the semiconductor memory device 200 of FIG. 2 will not be repeated, and a difference therebetween will be explained in detail.

The reference plate voltages Vp1R and Vp2R may be provided to the second terminals of the capacitors of the first reference cell MC and the second reference cell MC2R, respectively. Each of the reference plate voltages Vp1R and Vp2R may have the ground voltage Vss during precharging, and may have a voltage greater than the ground voltage Vss, for example, Vdd/2, during presensing and main sensing.

The equalizing unit EQ may include, for example, first through third equalizing transistors MN3′, MN4, and MN5. The control signal S_{EQ} may be provided to gates of the first through third equalizing transistors MN3′, MN4, and MN5. In response to the control signal S_{EQ}, the first through third equalizing transistors MN3′, MN4, and MN5 may equalize and precharge the first bit line BL1 and BL2 to the ground voltage Vss.

The first node SP of the sense amplifier SA may be connected to a fifth transistor MP3′ controlled by a control signal PSP, and the power supply voltage Vdd may be provided to the first node SP through the fifth transistor MP3′.

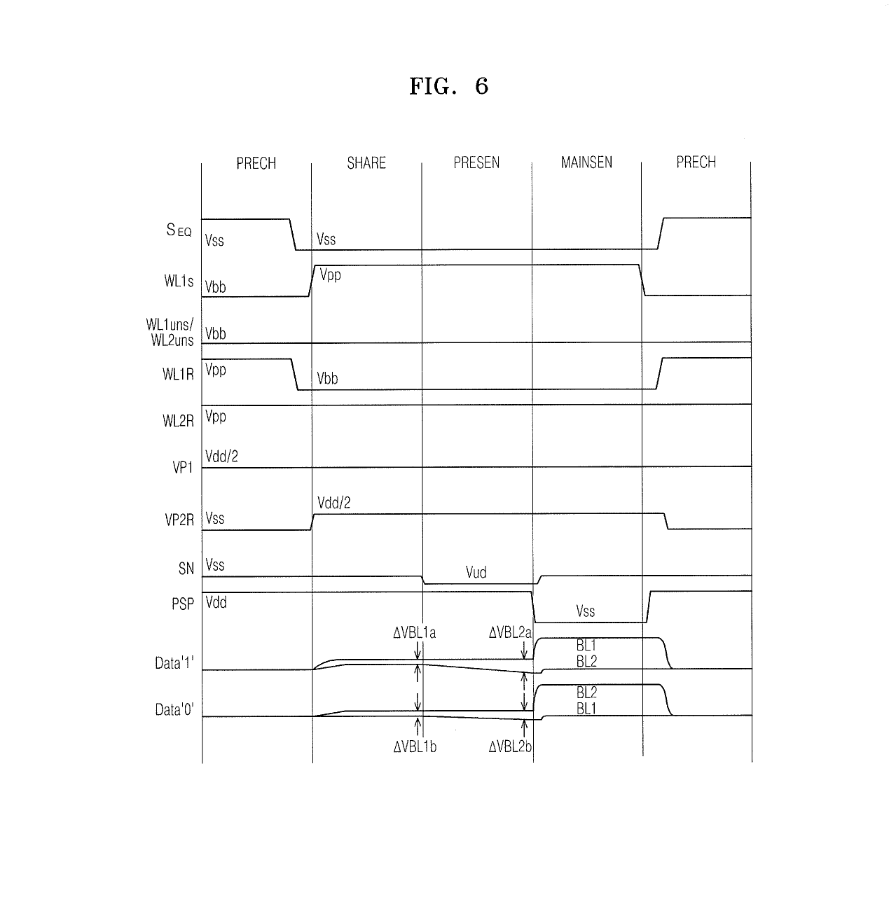

The second voltage providing unit VGN may be connected to the second node SN of the sense amplifier SA. The second voltage providing unit VGN may change a voltage of the second node SN as described above and as explained below in further detail with reference to a timing diagram of FIG. 6.

FIG. 6 illustrates a timing diagram for explaining a method of sensing data that is performed by the semiconductor memory device 300 of FIG. 5, according to an embodiment.

Referring to FIGS. 5 and 6, the method of sensing data performed by the semiconductor memory device 300 is similar to the method of sensing data performed by the semiconductor memory device 200 of FIGS. 2 and 3. A description of similar steps to those of the method of sensing data of the semiconductor memory device 200 will not be repeated, and a difference therebetween will be explained. In FIG. 6, the method of sensing data when data of one of the first memory cells MC1a through MC1n is sensed will be explained as an example. The same method may be used when data of one of the second memory cells MC2a through MC2n is detected.

The equalizing unit EQ of the semiconductor memory device 300 includes an NMOS transistor, unlike the equalizing unit EQ of the semiconductor memory device 200. When the control signal S_{EQ} is at the power supply voltage Vdd, the first and second bit lines BL1 and BL2 may be equalized to the ground voltage Vss. Signals of word lines WL1a-1n, WL2a-2n, WL1R, and WL2R are substantially the same as those of the timing diagram of FIG. 3.

In a precharging operation PRECH, the first through third equalizing transistors MN3′, MN4, and MN5 are turned on due to the control signal S_{EQ} of the power supply voltage Vdd, and both the first bit line BL1 and the second bit line BL2 are precharged to the ground voltage Vss.

Vdd/2 is provided to the second terminals of the capacitors of the first and second memory cells MC1a through MC1n and MC2a through MC2n, and the ground voltage Vss is provided to the second terminal of the capacitor of the second reference cell MC2R. The second voltage providing unit VGN provides the ground voltage Vss to the second node SN, and the fifth transistor MP3′ is turned off due to the control signal PSP of the power supply voltage Vdd.

Before the charge sharing operation SHARE, the control signal S_{EQ} transits to the ground voltage Vdd, and all of the first through third equalizing transistors MN3′, MN4, and MN5 are turned off. The word line WL1R transits to the low voltage Vbb, and the capacitor of the first reference cell MC1R is separated from the first bit line BL1.

In the charge sharing operation SHARE, the word line WL1s transits to the high voltage Vpp, and charges are shared between the first bit line BL1 and a capacitor of a selected memory cell in which data is to be sensed. When data of the selected memory cell is “1”, a voltage of the first bit line BL1 is increased. When the data of the selected memory cell is “0”, a voltage of the first bit line BL1 is not changed and is maintained at the ground voltage Vss.

At this time, a voltage applied to the second terminal of the capacitor of the second reference cell MC2R is increased to a predetermined voltage, and, thus, a voltage of the second bit line BL2 is increased to a voltage greater than the ground voltage Vss due to capacitive coupling. A time when a voltage applied to the second terminal of the capacitor of the second reference cell MC2R is increased to a predetermined voltage may not be the same as a time when the word line WL1s transits to the high voltage Vpp. In the present example embodiment, a voltage applied to the second terminal of the capacitor of the second reference cell MC2R is increased to Vdd/2. In other embodiments, the voltage may be increased to another voltage.

For example, when the voltage applied to the second terminal of the capacitor of the second reference cell MC2R is increased by Δv, a voltage of the second bit line BL2 is increased by {Cs/(Cs+Cbl)}Δv. Here, Cs denotes a capacitance of the capacitor of the second reference cell MC2R, and Cbl denotes a capacitance of a bit line capacitor. An amount by which the voltage of the second bit line BL2 is increased should be less than an amount by which a voltage of the first bit line BL1 is increased due to charge sharing when data of a selected memory cell is “1”.

Next, in the presensing operation PRESEN, the second voltage providing unit VGN provides an under-driving voltage Vud less than the ground voltage Vss to the second node SN. For example, the under-driving voltage Vod may be 0.1 to 0.4 times the power supply voltage Vdd. For example, the under-driving voltage Vud may range, for example, from −100 to −400 mV. The under-driving voltage Vud may be changed by using the second voltage providing unit VGN.

As the under-driving voltage Vud is provided to the second node SP, a transistor including a gate to which a higher voltage is applied from among the third transistor MN1 and the fourth transistor MN2 is weakly turned on, to reduce a voltage of the second bit line BL2 or the first bit line BL1 to, for example, the under-driving voltage Vud. In this case, an N-type latch comprised of the third transistor MN1 and the fourth transistor MN2 may be designed to operate at a sub-threshold voltage.

For example, when data of a selected memory cell is “0”, since a voltage of the second bit line BL2 is greater than a voltage of the first bit line BL1, the third transistor MN1 having the gate connected to the second bit line BL2 is weakly turned on. As a result, the first bit line BL1 is reduced to a voltage less than the ground voltage Vss. Accordingly, a difference in a voltage between the first bit line BL1 and the second bit line BL2 is further increased. A difference in a voltage between the first bit line BL1 and the second bit line BL2 is increased from ΔVBL1a to ΔVBL2a in FIG. 6. Thus, a sensing margin may be increased.

As another example, when the data of the selected memory cell is “1”, a voltage of the first bit line BL1 is increased to a value greater than a voltage of the second bit line BL2 due to charge sharing. The fourth transistor MN2 having the gate connected to the first bit line BL1 is weakly turned on, to reduce a voltage of the second bit line BL2. As a result, a difference in a voltage between the first bit line BL1 and the second bit line BL2 is further increased, thereby increasing a sensing margin. Thus, a difference in a voltage between the first bit line BL1 and the second bit line BL2 is increased from ΔVBL1b to L\VBL2b in FIG. 3.

A time when a voltage of the second node SN is reduced is a predetermined period of time after the charge sharing operation SHARE in FIG. 3. In other embodiments, a time when a voltage of the second node SN is reduced may be substantially the same as a time when the word line WL1s of a selected memory cell transits to the high voltage Vpp. In this case, the charge sharing operation SHARE and the presensing operation PRESEN may not be distinguished from each other.

In the main sensing operation MAINSEN, the control signal PSP transits to the ground voltage Vss, and the power supply voltage Vdd may be provided to the first node SP. As a result, a voltage of a bit line having a higher voltage from among the first bit line BL1 and the second bit line BL2 is increased to the power supply voltage Vdd. When the data of the selected memory cell is “1”, a voltage of the first bit line BL1 is increased to the power supply voltage Vdd, and, when the data is “0”, a voltage of the second bit line BL2 is increased to the power supply voltage Vdd.

Also, the second voltage providing unit VGN returns a voltage of the second node SN to the ground voltage Vss. As a result, when the data of the selected memory cell is “1”, a voltage of the second bit line BL2 is increased to the ground voltage Vss, and, when the data is “0”, a voltage of the first bit line BL1 is increased to the ground voltage Vss. A time when a voltage of the second node SN is returned to the ground voltage Vss is slightly later than a time when the control signal PSN transits to the ground voltage Vss in FIG. 6. In other embodiments, the times may be substantially the same.

As a result of the main sensing operation MAINSEN, when the data of the selected memory cell is “1”, the first bit line BL1 has the power supply voltage Vdd and the second bit line BL2 has the ground voltage Vss. When the data of the selected memory cell is “0”, the first bit line BL1 has the ground voltage Vss and the second bit line BL2 has the power supply voltage Vdd. Also, when data of a capacitor of the selected memory cell is “1”, the capacitor is charged to the power supply voltage Vdd, and, when the data is “0”, the capacitor is charged to the ground voltage Vss.

Next, in the precharging operation PRECH, the word line WL1s (which is a selected word line) transits to the low voltage Vbb, and a capacitor of a selected memory cell is separated from the first bit line BL1. Also, the control signal PSP transits to the power supply voltage Vdd, and the power supply voltage Vdd is not provided to the first node SP. Also, the control signal S_{EQ} transits to the power supply voltage Vdd, and both the first and second bit lines BL1 and BL2 are precharged to the ground voltage Vss. A voltage applied to the second terminal of the capacitor of the second reference cell MC2R is returned to the ground voltage Vss. Also, the word line WL1R of the first reference cell MC1R connected to the first bit line BL1 is returned to the high voltage Vpp.

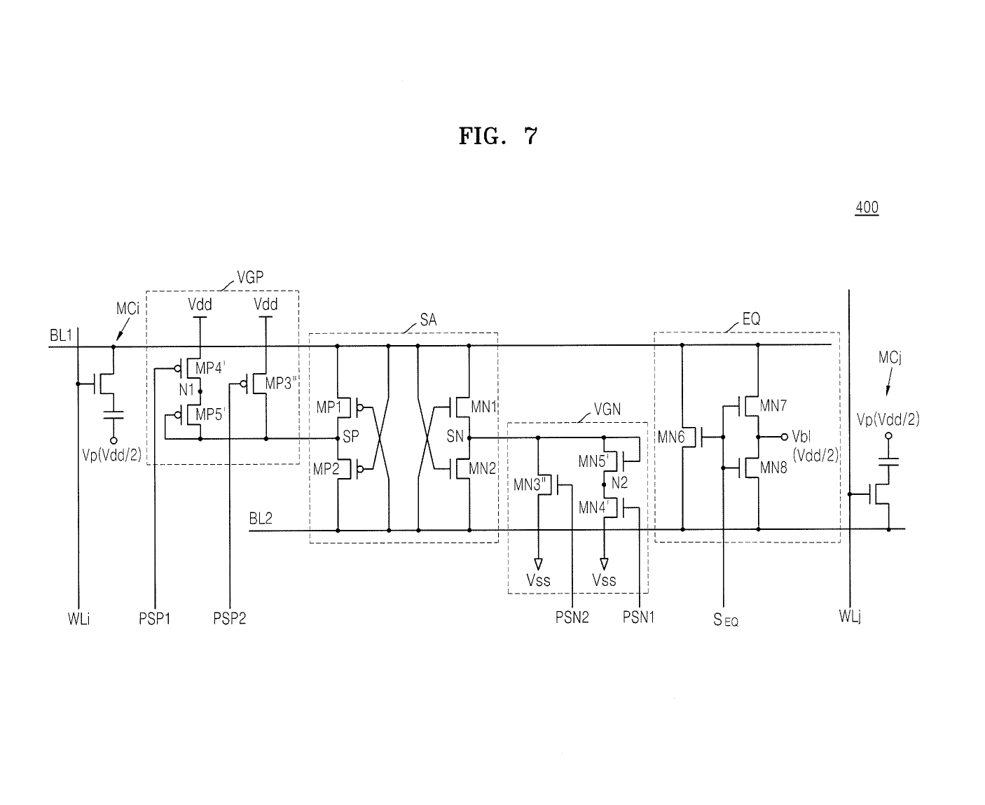

FIG. 7 illustrates a circuit diagram of a semiconductor memory device 400 according to another embodiment.

In the example embodiment shown in FIG. 7, the semiconductor memory device 400 includes the first bit line BL1 and the second bit line BL2, memory cells MC1 and MCj connected to the first and second bit lines BL1 and BL2, the sense amplifier SA, and the equalizing unit EQ. The description of same elements as those of the semiconductor memory device 100 of FIG. 1 will not be repeated.

The memory cells MCi and MCj (for storing data) are respectively connected to the first bit line BL1 and the second bit line BL2. The semiconductor memory device 400 may not include the first and second reference cells MC1R and MC2R, unlike the semiconductor memory devices 200 and 300. A plate voltage Vp, for example, a half of the power supply voltage Vdd, that is, Vdd/2, may be provided to second terminals of capacitors of the memory cells MCi and MCj.

The equalizing unit EQ may include first through third equalizing transistors MN6, MN7, and MN8. The control signal S_{EQ} may be provided to gates of the first through third equalizing transistors MN6, MN7, and MN8. The first equalizing transistor MN6 may connect the first bit line BL1 and the second bit line BL2 in response to the control signal S_{EQ}. The second equalizing transistors MN7 and the third equalizing transistor MN8 may equalize the first bit line BL1 and the second bit line BL2 in response to the control signal S_{EQ}.

The sense amplifier SA may include a P-type latch and an N-type latch. The P-type latch may include the first PMOS transistor MP1 and the second PMOS transistor MP2. The N-type latch may include the first NMOS transistor MN1 and the second NMOS transistor MN2. The first voltage providing unit VGP may be connected to the first node SP of the sense amplifier SA. Also, the second voltage providing unit VGN may be connected to the second node SN of the sense amplifier SA.

The first voltage providing unit VGP may include a third PMOS transistor MP3″ that provides the power supply voltage Vdd to the first node SP according to a second control signal PSP2. Also, the first voltage providing unit VGP may include a fourth PMOS transistor MP4′ that provides the power supply voltage Vdd to a node N1 according to a first control signal PSP1. Also, the first voltage providing unit VGP may include a first voltage dropping element MP5′ that provides a first voltage to the first node SP by dropping a voltage provided to the node N1. For example, the first voltage dropping element MP5′ may be a diode including a p-channel metal-oxide-semiconductor field-effect transistor (PMOSFET), as shown in FIG. 7. The first voltage may be less than the power supply voltage Vdd and greater than a half of the power supply voltage Vdd, that is, Vdd/2. The first voltage may be less than the power supply voltage Vdd by a threshold voltage of the first voltage dropping element MP5′. The threshold voltage may be adjusted by adjusting an impurity concentration of the first voltage dropping element MP5′.

The second voltage providing unit VGN may include a third NMOS transistor MN3″ that provides the ground voltage Vss to the second node SN according to a fourth control signal PSN2. Also, the second voltage providing unit VGN may include a fourth NMOS transistor MN4′ that provides the ground voltage Vss to the node N2 according to a third control signal PSN1. Also, the second voltage providing unit VGN may include a second voltage dropping element MN5′ that provides a second voltage to the first node SP by reversely dropping a voltage applied to the node N2. For example, the second voltage dropping element MN5′ may be a diode including an n-channel metal-oxide-semiconductor field-effect transistor (NMOSFET), as shown in FIG. 7. The second voltage may be greater than the ground voltage Vss and less than a half of the power supply voltage Vdd, that is, Vdd/2. The second voltage may be greater than the ground voltage Vss by a threshold voltage of the second voltage dropping element MN5. The threshold voltage may be adjusted by adjusting an impurity concentration of the second voltage dropping element MN5′.

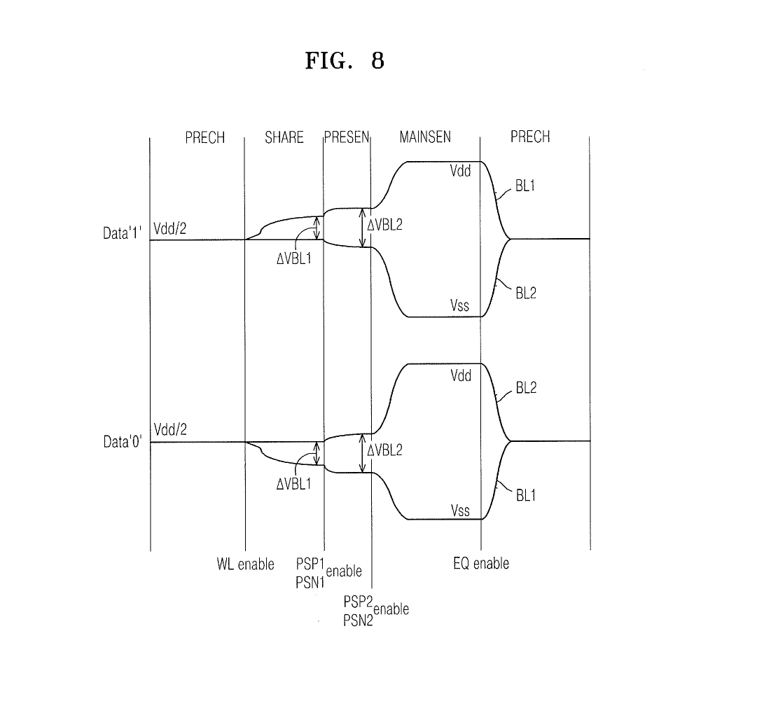

FIG. 8 illustrates a timing diagram for explaining a method of sensing data that is performed by the semiconductor memory device 400 of FIG. 7, according to an embodiment.

Referring to FIGS. 7 and 8, the method of sensing data may include the precharging operation PRECH, the charge sharing operation SHARE, the presensing operation PRESEN, and the main sensing operation MAINSEN. After the main sensing operation MAINSEN, the precharging operation PRECH may start again. The timing diagram of FIG. 8 shows a change in a voltage between the first and second bit lines BL1 and BL2 in each operation.

In the precharging operation PRECH, the first and second bit lines BL1 and BL2 are precharged to a predetermined voltage greater than the ground voltage Vss and less than the power supply voltage Vdd, for example, Vdd/2, due to the equalizing unit EQ.

In the charge sharing operation SHARE, a word line connected to a selected memory cell is activated, and charges are shared between a bit line and a capacitor of the selected memory cell. As a result, when data is “1”, a voltage of the first bit line BL1 is increased by ΔVBL1. When the data is “0”, a voltage of the first bit line BL1 is reduced by ΔVBL1. Here, it is assumed that the selected memory cell is connected to the first bit line BL1.

In the presensing operation PRESEN, the first and third control signals PSP1 and PSN1 are enabled, and, thus, a first voltage may be provided to the first node SP of a P-type latch and a second voltage may be provided to the second node SN of an N-type latch. As a result, the P-type latch and the N-type latch start operating at a sub-threshold voltage, and a difference in a voltage between the first and second bit lines BL1 and BL2 is further increased. That is, when the data is “1”, a voltage of the first bit line BL1 is increased to the first voltage and a voltage of the second bit line BL2 is reduced to the second voltage. When the data is “0”, a voltage of the first bit line BL1 is reduced to the second voltage and a voltage of the second bit line BL2 is increased to the first voltage. As a result, a difference in a voltage between the first and second bit lines BL1 and BL2 is increased from ΔVBL1 to ΔVBL2, thereby increasing a sensing margin.

In the main sensing MAINSEN, the second and fourth control signals PSP2 and PSN2 are enabled, and, thus, the power supply voltage Vdd may be provided to the first node SP of the P-type latch and the ground voltage Vss may be provided to the second node SN of the N-type latch. As a result, one of the first and second bit lines BL1 and BL2 may have the power supply voltage Vdd and the remaining one may have the ground voltage Vss. That is, when the data is “1”, the first bit line BL1 has the power supply voltage Vdd and the second bit line BL2 has the ground voltage Vss. When the data is “0”, the first bit line BL1 has the ground voltage Vss and the second bit line BL2 has the power supply voltage Vdd.

In the precharging operation PRECH, the first and second bit liens BL1 and BL2 are precharged to, for example, Vdd/2, due to the equalizing unit EQ.

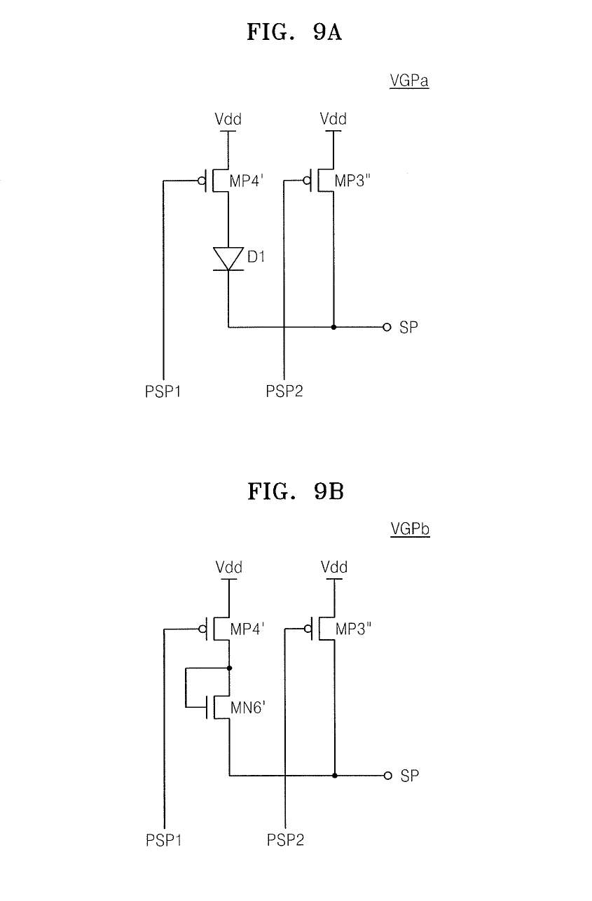

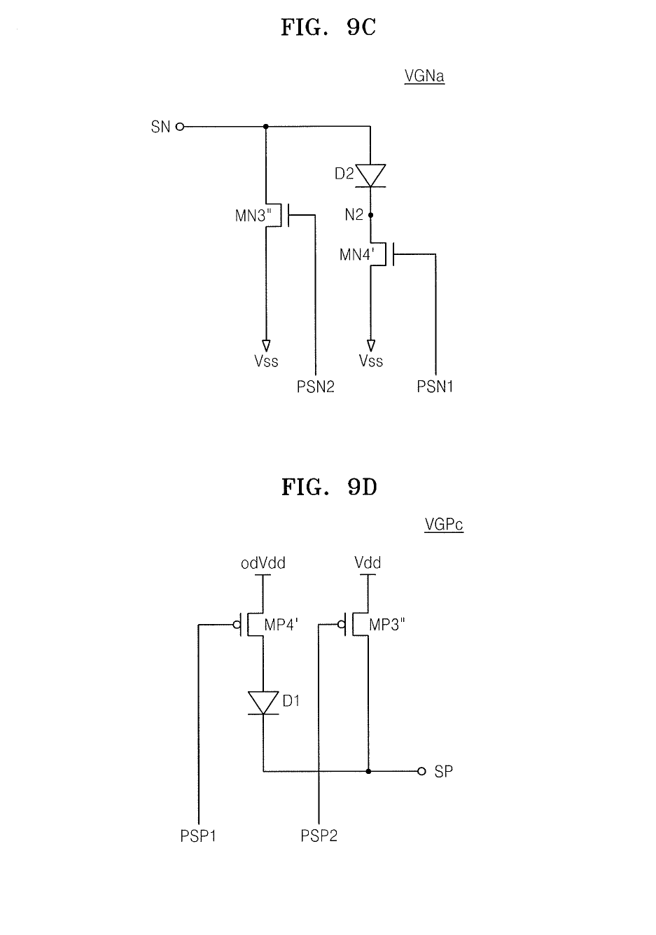

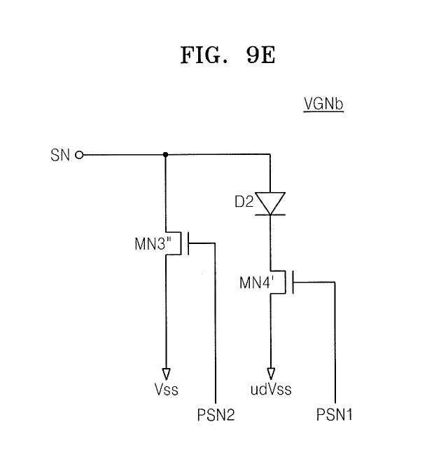

FIGS. 9A through 9E illustrate circuit diagrams of modified examples of the semiconductor memory device 400 of FIG. 7.

FIG. 9A illustrates a modified example VGPa of the first voltage providing unit VGP of the semiconductor memory device 400 of FIG. 7. As shown in FIG. 9A, the first voltage dropping element MP5′ may be replaced with a diode D1. A positive terminal of the diode D1 may be connected to the fourth PMOS transistor MP4′, and a negative terminal of the diode D1 may be connected to the first node SP.

FIG. 9B illustrates another modified example VGPb of the first voltage providing unit VGP of the semiconductor memory device 400 of FIG. 7. As shown in FIG. 9B, the first voltage dropping element MP5′ of FIG. 7 may be a diode including an NMOS transistor MN6′. A control electrode of the NMOS transistor MN6′ may be connected to the node N1. When the voltage dropping element MP5′ includes an NMOS transistor, the voltage dropping element MP5′ may be formed in a smaller area.

FIG. 9C illustrates a modified example VGNa of the second voltage providing unit VGN of the semiconductor memory device 400 of FIG. 7. As shown in FIG. 9C, the second voltage dropping element MN5′ of FIG. 7 may be replaced with a diode D2. A positive terminal of the diode D2 may be connected to the second node SN and a negative terminal of the diode D2 may be connected to the node N2.

FIG. 9D illustrates another modified example VGPc of the first voltage providing unit VGP of the semiconductor memory device 400 of FIG. 7. As shown in FIG. 9D, the power supply voltage Vdd may be provided to a first terminal of the third PMOS transistor MP3″, and an over-driving power supply voltage odVdd that is greater than the power supply voltage Vdd may be provided to a first terminal of the fourth PMOS transistor MP4′. A voltage applied to the first node SP may be adjusted during presensing by adjusting the over-driving power supply voltage odVdd.

FIG. 9E illustrates another modified example VGNb of the second voltage providing unit VGN of the semiconductor memory device 400 of FIG. 7. As shown in FIG. 9E, the ground voltage Vss may be provided to a second terminal of the third NMOS transistor MN3″, and an under-driving ground voltage udVss that is less than the ground voltage Vss may be provided to a second terminal of the fourth NMOS transistor MN4′. A voltage applied to the second node SN may be adjusted during presensing by adjusting the under-driving ground voltage udVss.

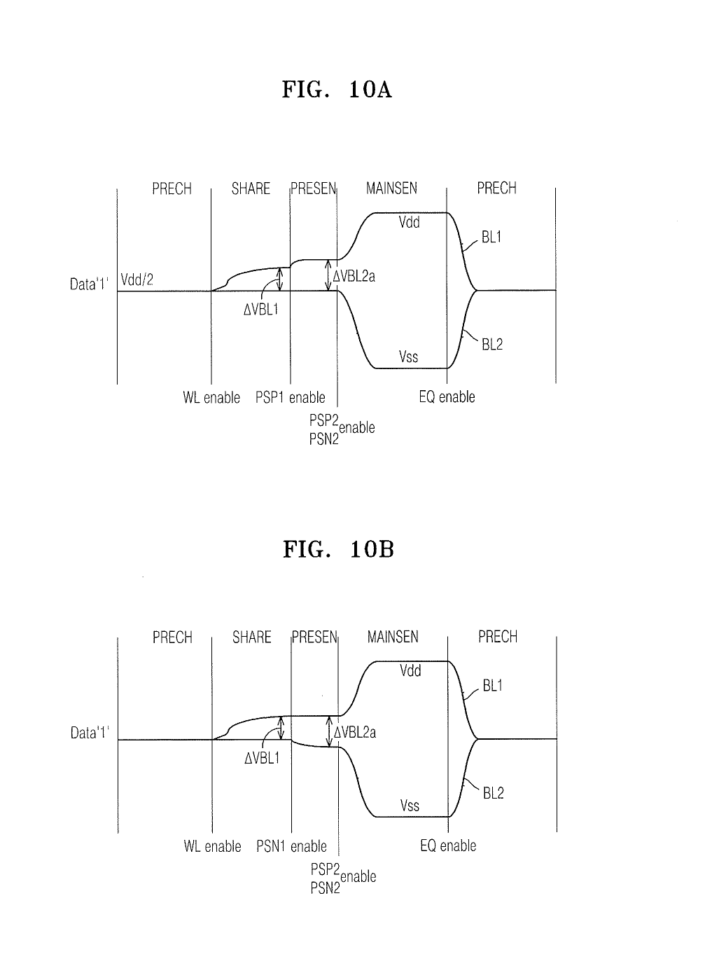

FIGS. 10A and 10B illustrate timing diagrams for explaining a method of sensing data that is performed by modified examples of the semiconductor memory device 400 of FIG. 7, according to an embodiment.

Details of FIGS. 10A and 10B that are substantially the same as the timing diagram of FIG. 8 will not be repeated.

Referring to FIG. 10A, the third control signal PSN1 is not provided, and the fourth NMOS transistor MN4′ and the second voltage dropping element MN5′ of the second voltage providing unit VGN of the semiconductor memory device 400 of FIG. 7 are not shown.

In this case, a bit line maintained at a precharge voltage, for example, Vdd/2, from among the first and second bit lines BL1 and BL2 is maintained at the precharge voltage even during a presensing operation PRESEN. That is, when data is “1”, the second bit line BL2 is maintained at a precharge voltage during the presensing operation PRESEN, and only a voltage of the first bit line BL1 is increased. However, even in this case, a difference in a voltage between the first and second bit lines BL1 and BL2 is increased from ΔVBL1 to ΔVBL2a, thereby increasing a sensing margin.

Referring to FIG. 10B, the first control signal PSP1 is not provided, and the fourth PMOS transistor MP4′ and the first voltage dropping element MP5′ of the first voltage providing unit VGP of the semiconductor memory device 400 of FIG. 7 are not shown.

In this case, a bit line maintained at a precharge voltage, for example, Vdd/2, from among the first and second bit lines BL1 and BL2 is reduced to a voltage equal to or less than the precharge voltage during a presensing operation PRESEN. That is, when data is “1”, a voltage of the second bit line BL2 during the presensing operation PRESEN is reduced to a voltage less than a precharge voltage, and a voltage of the first bit line BL1 is maintained at an increased level during a charge sharing operation SHARE. However, even in this case, a difference in a voltage between the first and second bit lines BL1 and BL2 is increased from ΔVBL1 to ΔVBL2b, thereby increasing a sensing margin.

It will be understood that, although the timing diagrams when data is “1” are shown in FIGS. 10A and 10B, the same may apply even when data is “0”.

Conductivity types of transistors shown in the circuit diagrams of FIGS. 1, 2, 5, and 7 may vary according to designs. Also, signals in the timing diagrams of FIGS. 3 and 6 may vary; widths of steps in the timing diagrams may be arbitrarily illustrated rather than representing actual time intervals.

According to embodiments, the first and second voltage providing units VGP and VGN added to any semiconductor memory device according to the inventive concept may not be separately disposed for one sense amplifier SA. In an embodiment, the first and second voltage providing units VGP and VGN may be commonly connected to a plurality of the sense amplifiers SA. Accordingly, even though circuits of the first and second voltage providing units VGP and VGN are added, the area of the semiconductor memory device may not be significantly increased. Also, a data sensing margin of the semiconductor memory device of the inventive concept is improved as described above. Thus, a power supply voltage equal to or less than 1 V may be used and a size of a capacitor of a memory cell may be reduced.

By way of summation and review, in a method of precharging bit lines to a power supply voltage Vdd, a mismatch between transistors of a sense amplifier may be used in order to sense data “1”. As power supply voltage in the semiconductor memory device decreases, a data sensing margin may also decrease, such that it may become difficult to identify the data stored in the memory cell.

A method of applying a reference cell to a complementary bit line may be used. In this case, it is important to ensure a sensing margin. A semiconductor memory device according to an example embodiment may increase a data sensing margin.

As described above, embodiments relate to a semiconductor memory device of which an operation includes presensing performed between charge sharing and main sensing.

According to an example embodiment, in a method of precharging bit lines to a power supply voltage Vdd, a sensing margin may be increased by over-driving a driving voltage of a P-type latch to a voltage greater than the power voltage level Vdd during charge sharing. Also, in a method of precharging bit lines to a ground voltage Vss, a sensing margin may be increased by under-driving a driving voltage of an N-type latch to a voltage less than the ground voltage level Vss during charge sharing.

Also, in a method of precharging bit lines to Vdd/2, presensing may be performed between charge sharing and main sensing. A sensing margin may be increased by driving a P-type latch to a voltage greater than Vdd/2 and less than Vdd and/or by driving an N-type latch to a voltage greater than Vss and less than Vdd/2.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, operations of which include precharging, charge sharing, presensing, and main sensing that are sequentially performed, the semiconductor memory device comprising:
a first bit line to which a first memory cell is connected, and a second bit line to which a second memory cell is connected, the second bit line being complementary to the first bit line;
a sense amplifier that includes a first transistor and a second transistor connected in series between the first bit line and the second bit line, the sense amplifier including a first node between the first transistor and the second transistor, a gate of the first transistor being connected to the second bit line, and a gate of the second transistor being connected to the first bit line; and
a voltage providing unit that provides a first voltage to the first node during the presensing, and provides a second voltage, different from the first voltage, to the first node during the main sensing.

2. The semiconductor memory device as claimed in claim 1, wherein:
the first memory cell includes a first switching element and a first capacitor, the first switching element including a control terminal connected to a first word line, a first terminal connected to the first bit line, and a second terminal connected to a first terminal of the first capacitor, and the first capacitor including a second terminal to which a first plate voltage is provided,
the second memory cell includes a second switching element and a second capacitor, the second switching element including a control terminal connected to a second word line, a first terminal connected to the second bit line, and a second terminal connected to a first terminal of the second capacitor, and the second capacitor including a second terminal to which a second plate voltage is provided, and
the second plate voltage is changed independently of the first plate voltage.

3. The semiconductor memory device as claimed in claim 2, wherein:
the first bit line and the second bit line are precharged to a power supply voltage during the precharging, and
the voltage providing unit provides the first voltage, which is greater than the second voltage, to the first node during the presensing.

4. The semiconductor memory device as claimed in claim 3, wherein the second voltage is the power supply voltage, the first voltage is greater than the second voltage by a predetermined amount, and the predetermined amount is adjustable.

5. The semiconductor memory device as claimed in claim 2, wherein:
the first bit line and the second bit line are precharged to a ground voltage during the precharging, and
the voltage providing unit provides the first voltage, which is less than the second voltage, to the first node during the presensing.

6. The semiconductor memory device as claimed in claim 5, wherein the second voltage is the ground voltage, the first voltage is less than the second voltage by a predetermined amount, and the predetermined amount is adjustable.

7. The semiconductor memory device as claimed in claim 1, wherein:
the first bit line and the second bit line are precharged to a third voltage, which is greater than a ground voltage and less than a power supply voltage, during the precharging, and
the first voltage is between the second voltage and the third voltage.

8. The semiconductor memory device as claimed in claim 7, wherein the voltage providing unit includes:
a voltage supply source that provides the second voltage;
a first switching element that applies the second voltage of the voltage supply source to the first node during the main sensing;
a voltage dropping element that generates the first voltage from the second voltage of the voltage supply source; and
a second switching element that applies the first voltage to the first node by using the voltage dropping element during the presensing.

9. The semiconductor memory device as claimed in claim 8, wherein the voltage dropping element is a transistor or a diode.

10. The semiconductor memory device as claimed in claim 8, wherein the first voltage is greater or less than the second voltage by a threshold voltage of the voltage dropping element.

11. The semiconductor memory device as claimed in claim 10, wherein the threshold voltage is adjusted by adjusting an impurity concentration of the voltage dropping element.

12. The semiconductor memory device as claimed in claim 8, wherein the voltage supply source provides the second voltage, which is greater than the power supply voltage and less than the ground voltage, during the charge sharing and the presensing.

13. The semiconductor memory device as claimed in claim 7, wherein:
the sense amplifier includes a first amplifying unit including the first transistor and the second transistor, and a second amplifying unit including a third transistor and a fourth transistor;
the third transistor includes a first terminal connected to the first bit line, a gate connected to the second bit line, and a second terminal connected to a second node,
the fourth transistor includes a first terminal connected to the second bit line, a gate connected to the first bit line, and a second terminal connected to the second node, and
the voltage providing unit provides a fourth voltage to the second node during the main sensing, and provides a fifth voltage, which is between the fourth voltage and the third voltage, to the second node during the presensing.

14. The semiconductor memory device as claimed in claim 13, wherein one of the second voltage and the fourth voltage is the power supply voltage, and the other one is the ground voltage.

15. A semiconductor memory device, operations of which include precharging, charge sharing, presensing, and main sensing that are sequentially performed, the semiconductor memory device comprising:
a first bit line and a second bit line that are complementary to each other and are precharged to a first voltage which is greater than a ground voltage and less than a power supply voltage;
a first transistor that includes a first terminal connected to the first bit line, a gate connected to the second bit line, and a second terminal connected to a first node;
a second transistor that includes a first terminal connected to the second bit line, a gate connected to the first bit line, and a second terminal connected to the first node; and
a voltage providing unit that provides a second voltage to the first node during the main sensing, and provides a third voltage, which is between the first voltage and the second voltage, to the first node during the presensing.

16. A semiconductor memory device, comprising:
a first bit line;
a second bit line;
a sense amplifier, the sense amplifier having a first transistor connected to the first bit line and having a second transistor connected to the second bit line, the first and second transistors being connected to each other in series between the first and second bit lines; and
a voltage providing unit coupled to a node in the sense amplifier between the first and second transistors, the voltage providing unit providing an adjustable voltage to the node, the voltage being adjusted to a first level during a presensing operation, during which a voltage difference between the first bit line and the second bit line is amplified by the sense amplifier, and being adjusted to a second level during a main sensing operation, which immediately follows the presensing operation and during which the sense amplifier further amplifies the voltage difference, the second level being different from the first level.

17. The semiconductor memory device as claimed in claim 16, wherein the first and second transistors are each PMOS transistors, and the first level is greater than the second level.

18. The semiconductor memory device as claimed in claim 17, wherein the semiconductor memory device is supplied with a power supply voltage and a ground voltage, the power supply voltage being greater than the ground voltage, and the second level is equal to the power supply voltage.

19. The semiconductor memory device as claimed in claim 16, wherein the first and second transistors are each NMOS transistors, and the first level is less than the second level.

20. The semiconductor memory device as claimed in claim 19, wherein the semiconductor memory device is supplied with a power supply voltage and a ground voltage, the power supply voltage being greater than the ground voltage, and the second level is equal to the ground voltage.
